(19) United States
(12) Patent Application Publication
(10) Pub. No.: US 2026/0239756 A1
(43) Pub. Date: Aug. 13, 2026

(54) SEMICONDUCTOR PACKAGE AND METHOD OF MANUFACTURING THE SEMICONDUCTOR PACKAGE

(71) Applicant: SUMSUNG ELECTRONICS CO., LTD., Suwon-si (KR)

(72) Inventors: Goonwoo Kim, Suwon-si (KR); Junyoung Ko, Suwon-si (KR); Sunkyu Hwang, Suwon-si (KR)

(73) Assignee: SUMSUNG ELECTRONICS CO., LTD., Suwon-si (KR)

(21) Appl. No.: 19/538,176

(22) Filed: Feb. 12, 2026

(30) Foreign Application Priority Data
Feb. 12, 2025 (KR) 10-2025-0017834

(51) Int. Cl. H10F 39/00

(52) U.S. Cl. CPC H10F 39/804; H10F 39/8063; H10F 39/811; H10F 39/024

(57) ABSTRACT

A semiconductor package includes: a package substrate including upper substrate pads on an upper surface of the package substrate; an image sensor chip on the upper surface of the package substrate, the image sensor chip including chip pads on an upper surface of the image sensor chip; bonding wires connecting the upper substrate pads of the package substrate and the chip pads; a lens-covering portion including a glass and an adhesive film portion having an annular shape or a rectangular ring shape on a lower surface of the glass, the lens-covering portion being adhered on the image sensor chip by the adhesive film portion between the image sensor chip and the glass; and a molding member on the image sensor chip and the bonding wires.

### CROSS-REFERENCE TO RELATED APPLICATION

This application claims priority benefit of under 35 U.S.C. § 119 to Korean Patent Application No. 10-2025-0017834, filed on February 12, 2025 in the Korean Intellectual Property Office (KIPO), the disclosures of which are herein incorporated by reference in their entirety.

### BACKGROUND

### Field

Example embodiments relate to a semiconductor package and method of manufacturing the semiconductor package, and more particularly, to a semiconductor package including a CMOS Image Sensor (CIS) chip and a method of manufacturing the same.

### Description of Related Art

In manufacturing a semiconductor package having a CMOS Image Sensor (CIS) chip, a glass may be disposed on a sensor chip to protect micro lenses formed on a surface of the sensor chip. For example, an adhesive may be applied to the surface of the sensor chip to form a dam structure, and the glass may be attached to a top of the dam structure so that the glass is supported by the dam structure. However, because the adhesive comprises a liquid adhesive, there is a risk that foreign substances may be scattered on the micro lenses during the application process and contaminate the sensor. Furthermore, the liquid adhesive may vary in thickness at portions thereof, which may result in the glass being unevenly applied and/or tilted. The tilted glass may prevent light from being evenly incident on the sensor chip, which reduces the quality of the image sensor as a result. In addition, the liquid adhesive requires a separate curing process, which deteriorates workability.

### SUMMARY

One or more example embodiments provide a semiconductor package that may prevent damage to a sensor chip and improve the performance of the image sensor chip.

One or more example embodiments provide a method of manufacturing the semiconductor package.

According to an aspect of the disclosure, a semiconductor package includes: a package substrate including upper substrate pads on an upper surface of the package substrate; an image sensor chip on the upper surface of the package substrate, the image sensor chip including chip pads on an upper surface of the image sensor chip; bonding wires connecting the upper substrate pads of the package substrate and the chip pads; a lens-covering portion including a glass and an adhesive film portion having an annular shape or a rectangular ring shape on a lower surface of the glass, the lens-covering portion being adhered on the image sensor chip by the adhesive film portion between the image sensor chip and the glass; and a molding member on the image sensor chip and the bonding wires.

According to an aspect of the disclosure, a semiconductor package includes: a package substrate; an image sensor chip on an upper surface of the package substrate, the image sensor chip including a sensing region, an adhesive region surrounding the sensing region, a pad region surrounding the adhesive region, and chip pads on the pad region; bonding wires connecting upper substrate pads of the package substrate and the chip pads; a lens-covering portion including an adhesive film portion on the adhesive region of the image sensor chip and a glass on the adhesive film portion, the glass on the sensing region; and a molding member on the image sensor chip and the bonding wires, wherein the adhesive film portion includes: a first adhesive film pattern on the adhesive region of the image sensor chip; and a second adhesive film pattern on the first adhesive film pattern, the second adhesive film pattern including a photocurable material.

According to an aspect of the disclosure, a semiconductor package includes: a package substrate; an image sensor chip on an upper surface of the package substrate, the image sensor chip being electrically connected to the package substrate and including a sensing region and an adhesive region around the sensing region; a first adhesive film pattern on the adhesive region of the image sensor chip and having a first width; a second adhesive film pattern on the first adhesive film pattern, the second adhesive film pattern having a second width substantially equal to the first width, the second adhesive film pattern including a photocurable material; a lens-covering portion including a glass on the second adhesive film pattern and the sensing region; and a molding member on the image sensor chip, wherein the molding member is on an outer surface of the first adhesive film pattern, an outer surface of the second adhesive film pattern, and an outer surface of the glass.

According to an aspect of the disclosure, a method of manufacturing a semiconductor package, includes: preparing a package substrate including upper substrate pads; disposing an image sensor chip on the package substrate, the image sensor chip including a lens layer in a sensing region and chip pads in a pad region surrounding the sensing region; connecting the chip pads of the image sensor chip and the upper substrate pads via bonding wires; forming, on the image sensor chip, a lens-covering portion including a glass and an adhesive film portion having an annular shape or a rectangular ring shape on a lower surface of the glass; attaching the adhesive film portion of the lens-covering portion on the image sensor chip; and forming a molding member on the image sensor chip and the bonding wires.

Accordingly, in contrast with related art that uses a dam structure or spacer comprising epoxy, polyimide-based resin, photocurable polymer, photocurable epoxy, etc., to attach a transparent plate member such as glass on an image sensor chip, the semiconductor package according to one or more example embodiments of the disclosure may comprise the integrated lens cover portion comprising the adhesive film portion made of a die attach film (DAF) material. Because the adhesive film portion may exhibit a small height difference between different portions thereof, the glass supported by the adhesive film portion may be on the image sensor chip without being bent or tilted, so that the light incident on the glass may be focused on the lens without being distorted, thereby providing a more reliable semiconductor package.

### BRIEF DESCRIPTION OF DRAWINGS

One or more example embodiments will be more clearly understood from the following detailed description taken in conjunction with the accompanying drawings. FIGS. 1 to 21 may represent one or more non-limiting example embodiments as described herein.

FIGS. 1, 2, and 3 are views illustrating a semiconductor package in accordance with one or more example embodiments.

FIGS. 4, 5, 6, 7, 8, 9, 10, 11, 12, 13, 14, 15, 16, 17, and 18 are views illustrating a method of manufacturing a semiconductor package in accordance with one or more example embodiments.

FIGS. 19 and 20 are views illustrating a semiconductor package in accordance with one or more example embodiments.

FIG. 21 is a view illustrating a method of manufacturing a semiconductor package in accordance with one or more example embodiments.

### DETAILED DESCRIPTION

All of the embodiments of the disclosure described herein are example embodiments, and thus, the disclosure is not limited thereto, and may be realized in various other forms. Each of the embodiments provided in the following description is not excluded from being associated with one or more features of another example or another embodiment also provided herein or not provided herein but consistent with the disclosure.

It will be understood that when an element, component, layer, pattern, structure, region, or so on (hereinafter collectively “element”) of a semiconductor device is referred to as being “over,” “above,” “on,” “below,” “under,” “beneath,” “connected to” or “coupled to” another element of the semiconductor device, it can be directly over, above, on, below, under, beneath, connected or coupled to the other element or an intervening element(s) may be present. In contrast, when an element of a semiconductor device is referred to as being “directly over,” “directly above,” “directly on,” “directly below,” “directly under,” “directly beneath,” “directly connected to” or “directly coupled to” another element of the semiconductor device, there are no intervening elements present. Like numerals refer to like elements throughout this disclosure.

As used herein, the term “and/or” includes any and all combinations of one or more of the associated listed items. As used herein, expressions such as “at least one of,” when preceding a list of elements, modify the entire list of elements and do not modify the individual elements of the list. For example, the expression, “at least one of a, b and c,” and “at least one of a, b, or c” should be understood as including only a, only b, only c, both a and b, both a and c, both b and c, or all of a, b and c.

It will be also understood that, even if a certain step or operation of manufacturing an apparatus or structure is described later than another step or operation, the step or operation may be performed later than the other step or operation unless the other step or operation is described as being performed after the step or operation.

Hereinafter, one or more example embodiments will be explained in detail with reference to the accompanying drawings.

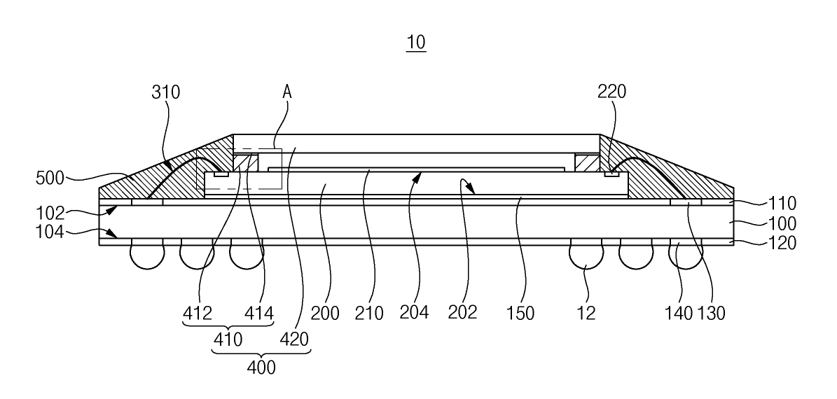

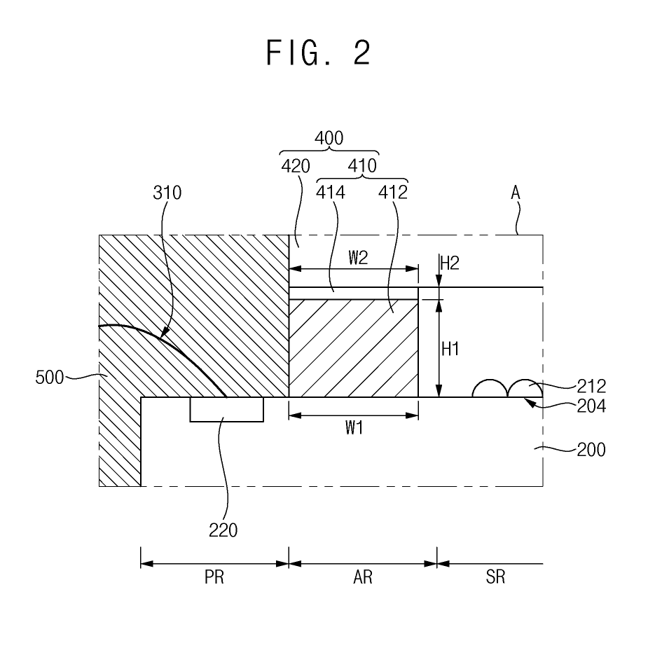

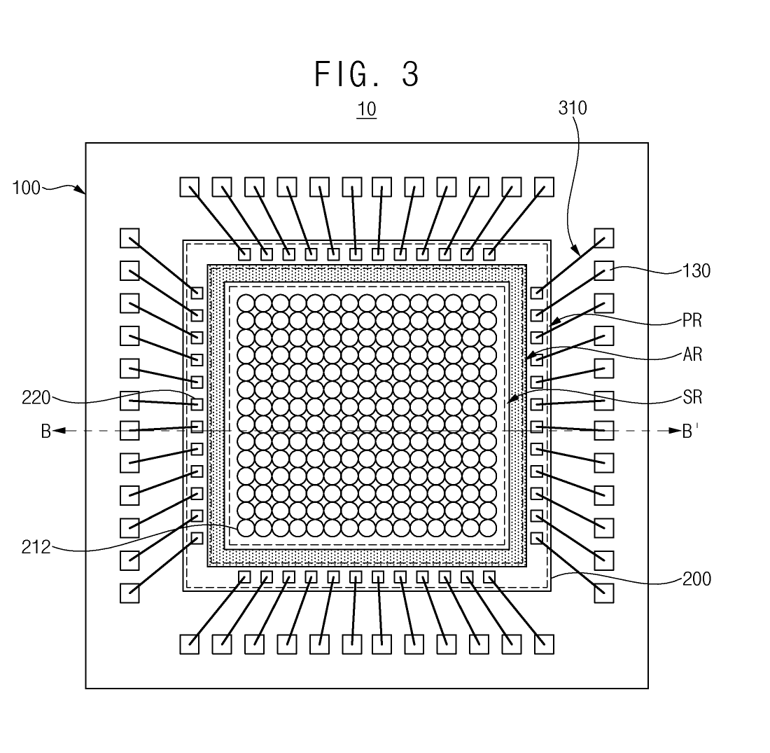

FIG. 1 is a cross-sectional view illustrating a semiconductor package in accordance with one or more example embodiments. FIG. 2 is an enlarged cross-sectional view illustrating portion ‘A’ in FIG. 1. FIG. 3 is a plan view illustrating the semiconductor package in FIG. 1. FIG. 1 is a cross-sectional view taken along the line B-B’ in FIG. 3. FIG. 3 is a plan view illustrating the semiconductor package of FIG. 1, wherein a molding member is omitted.

Referring to FIGS. 1 to 3, a semiconductor package 10 may include a package substrate 100, an image sensor chip 200 disposed on the package substrate 100, a lens-covering portion 400 disposed on the image sensor chip 200, and a molding member 500 disposed on the image sensor chip 200. Additionally, the semiconductor package 10 may further include bonding wires 310 that electrically connect the image sensor chip 200 to the package substrate 100, and an external connection member 12 that is disposed on a bottom surface of the package substrate 100.

In one or more example embodiments, the semiconductor package 10 may be an image sensor package including the image sensor chip 200 for converting an optical signal into an electrical signal. For example, the semiconductor package 10 may be an image sensor package including the image sensor chip 200 of CIS (CMOS image sensor) type.

In one or more example embodiments, the package substrate 100 may be a multilayer circuit board as a package substrate comprising an upper surface 102 and a lower surface 104 opposite the upper surface 102. For example, the package substrate 100 may be a printed circuit board (PCB) including wirings respectively provided in a plurality of layers and vias for electrically interconnecting the wirings.

The package substrate 100 may include an upper insulation layer 110 disposed on the upper surface 102 and a lower insulation layer 120 disposed on the lower surface 104. Additionally, the package substrate 100 may include upper substrate pads 130 and lower substrate pads 140.

The upper insulation layer 110 may be disposed on the upper surface 102 of the package substrate 100 to expose the upper substrate pads 130. The upper substrate pads 130 may be disposed in a peripheral area of the package substrate 100. The upper insulation layer 110 may cover the entire upper surface 102 of the package substrate 100 except for the upper substrate pads 130. For example, the upper insulation layer 110 may include a solder resist, but is not limited thereto.

The lower insulation layer 120 may be disposed on the lower surface 104 of the package substrate 100 to expose the lower substrate pads 140 as external connection pads for providing electrical signals. The lower substrate pads 140 may be exposed by the lower insulation layer 120. The lower insulation layer 120 may include a solder resist, but is not limited thereto. As will be described later, the external connection member 12 may be disposed on the lower substrate pad 140 of the package substrate 100 to facilitate electrical connection with an external device. For example, the external connection member 12 may comprise a solder ball, bump, and/or pillar, but is not limited thereto. For instance, the external connection member 12 may comprise any one or more structures or combinations of structures, and comprise any one or more materials appropriate for facilitating electrical interconnection. The semiconductor package 10 may be mounted on a module substrate via the solder balls to constitute an image sensor module.

In one or more example embodiments, the image sensor chip 200 may be mounted on the upper surface 102 of the package substrate 100. For example, the image sensor chip 200 may be attached onto the upper surface 102 of the package substrate 100 by an adhesive layer 150. The image sensor chip 200 may have a first surface 202 and a second surface 204 opposite the first surface 202. The image sensor chip 200 may be disposed on the package substrate 100 such that the first surface 202 faces the upper surface 102 of the package substrate 100.

The image sensor chip 200 may have a sensing region SR, an adhesive region AR surrounding the sensing region SR, and a pad region PR surrounding the adhesive region AR on the second surface 204. The image sensor chip 200 may include a lens layer 210 in the sensing region SR. The image sensor chip 200 may include chip pads 220 in the pad region PR.

The lens layer 210 may include a plurality of lenses 212. The plurality of lenses 212 may include hemispherical microlenses arranged in an array form on the sensing region SR. The hemispherical microlenses may focus an incident light on the image sensor chip 200.

The chip pads 220 may be arranged on the pad region PR to surround the adhesive region AR. The chip pads 220 may be exposed from the second surface 204 of the image sensor chip 200. Upper surfaces of the chip pads 220 may be positioned on the same plane as the second surface 204 of the image sensor chip 200. The chip pads 220 may be portions to which the bonding wires 310 are connected, respectively, as will be described later.

In one or more example embodiments, the bonding wires 310 may electrically connect the package substrate 100 to the image sensor chip 200. For example, the bonding wires 310 may extend, respectively, from the chip pad 220 on the second surface 204 of the image sensor chip 200 to the upper substrate pad 130 on the upper surface 102 of the package substrate 100 to electrically connect the chip pad 220 to the upper substrate pad 130. That is, a first end of one or more of the bonding wires 310 may be connected to the chip pad 220, and a second end of the one or more bonding wires 310 opposite the first end may be connected to the upper substrate pad 130. The bonding wires 310 may include gold (Au), copper (Cu), silver (Ag), aluminum (Al), etc.

In one or more example embodiments, the lens-covering portion 400 may be disposed on the second surface 204 of the image sensor chip 200. The lens-covering portion 400 may include an adhesive film portion 410 and a glass 420 that is disposed on the adhesive film portion 410.

The adhesive film portion 410 may be disposed on the adhesive region AR of the image sensor chip 200. The adhesive film portion 410 may surround the sensing region SR on the second surface 204 of the image sensor chip 200. For example, the adhesive film portion 410 may extend along a peripheral region of the image sensor chip 200 and have a rectangular ring shape, an annular shape, or any other polygonal ring shape, but is not limited thereto.

The adhesive film portion 410 may adhere the glass 420 to the image sensor chip 200 and support the glass 420. Additionally, the adhesive film portion 410 may protect the image sensor chip 200 from external moisture or pollutants.

The adhesive film portion 410 may include a first adhesive film pattern 412 and a second adhesive film pattern 414 disposed on the first adhesive film pattern 412. The first adhesive film pattern 412 may be disposed on the adhesive region AR of the image sensor chip 200 to surround the sensing region SR. The first adhesive film pattern 412 may have a first thickness H1 measured from the second surface 204 of the image sensor chip 200. The first adhesive film pattern 412 may extend in a vertical direction perpendicular to the second surface 204. The first thickness H1 may be within a range of about 5 μm to about 60 μm. The first adhesive film pattern 412 may have a first width W1 and comprise a rectangular ring shape, an annular shape, or any other polygonal ring shape, but is not limited thereto. The first adhesive film pattern 412 may include an adhesive film material such as a die attach film (DAF).

The second adhesive film pattern 414 may be disposed on the first adhesive film pattern 412. The second adhesive film pattern 414 may have a second thickness H2 measured from a top surface of the first adhesive film pattern 412. The second thickness H2 may be less than the first thickness H1. For example, the second thickness H2 may be within a range of about 5 μm or less. The second adhesive film pattern 414 may have a second width W2 and include a rectangular ring shape, an annular shape, or any other polygonal ring shape, but is not limited thereto. The second width W2 may be substantially equal to the first width W1. For example, the second adhesive film pattern 414 may have a shape corresponding to the shape of the first adhesive film pattern 412. The second adhesive film pattern 414 may include a photocurable adhesive material. The photocurable adhesive material may include an ultraviolet (UV) curable adhesive material and a pressure sensitive adhesive (PSA).

In one or more example embodiments, the glass 420 may be disposed on the second surface 204 of the image sensor chip 200. For example, the glass 420 may be disposed on the adhesive film portion 410 to be supported by the adhesive film portion 410 disposed on the image sensor chip 200. That is, the glass 420 may be spaced apart from the second surface 204 of the image sensor chip 200 by the height H1 of the adhesive film portion 410. When viewed in a plan view, an outer surface of the glass 420 may be positioned on the same plane as an outer surface of the adhesive film portion 410. The glass 420 may allow an optical signal to reach the lens layer 210 on the image sensor chip 200. The glass 420 may include a material such as transparent glass or transparent resin, but is not limited thereto.

In one or more example embodiments, the molding member 500 may be disposed on the package substrate 100 to cover the image sensor chip 200 and the bonding wires 310. The molding member 500 may be disposed to cover a side surface of the glass 420. The molding member 500 may be disposed to be in contact with a portion of a lower surface of the glass 420, an outer surface of the lens-covering portion 400, and a portion of the second surface 204 of the image sensor chip 200. The molding member 500 may prevent the lens layer 210 of the image sensor chip 200 from being contaminated by external foreign substances together with the lens-covering portion 400. Additionally, the molding member 500 may protect the semiconductor package 10 including the image sensor chip 200 from external impacts.

As described above, the semiconductor package 10 may include the package substrate 100, the image sensor chip 200 disposed on the package substrate 100 and comprising the chip pads 220, the bonding wires 310 electrically connecting the chip pads 220 of the image sensor chip 200 to the substrate pads 130 of the package substrate 100, the lens-covering portion 400 covering the image sensor chip 200, and the molding member 500. Additionally, the lens-covering portion 400 may comprise the adhesive film portion 410 and the glass 420 thereon.

Accordingly, in contrast with related art that uses a dam structure or spacer comprising epoxy, polyimide-based resin, photocurable polymer, photocurable epoxy, etc., to attach a transparent plate member such as glass on an image sensor chip, the semiconductor package according to one or more example embodiments of the disclosure may comprise the integrated lens cover portion comprising the adhesive film portion made of a die attach film (DAF) material. Because the adhesive film portion may exhibit a small height difference between different portions thereof, the glass 420 supported by the adhesive film portion may be disposed on the image sensor chip 200 without being bent or tilted, so that the light incident on the glass 420 may be focused on the lens without being distorted, thereby providing a more reliable semiconductor package.

Hereinafter, a method of manufacturing the semiconductor package of FIG. 1 will be described.

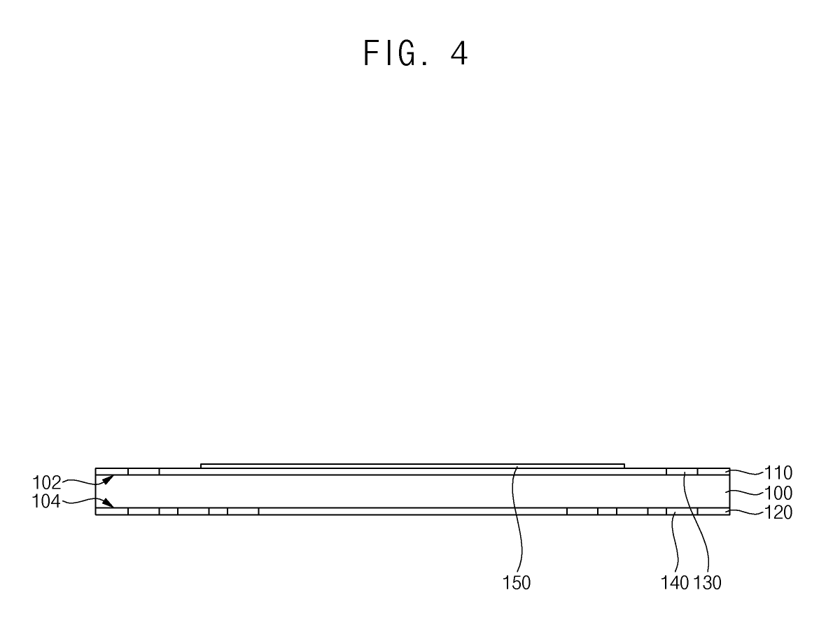

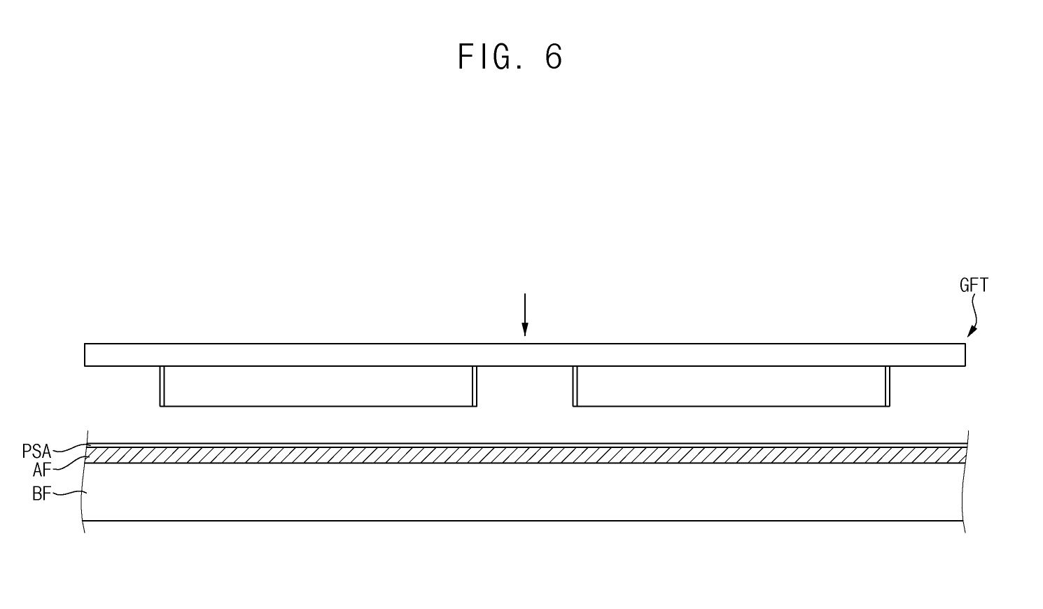

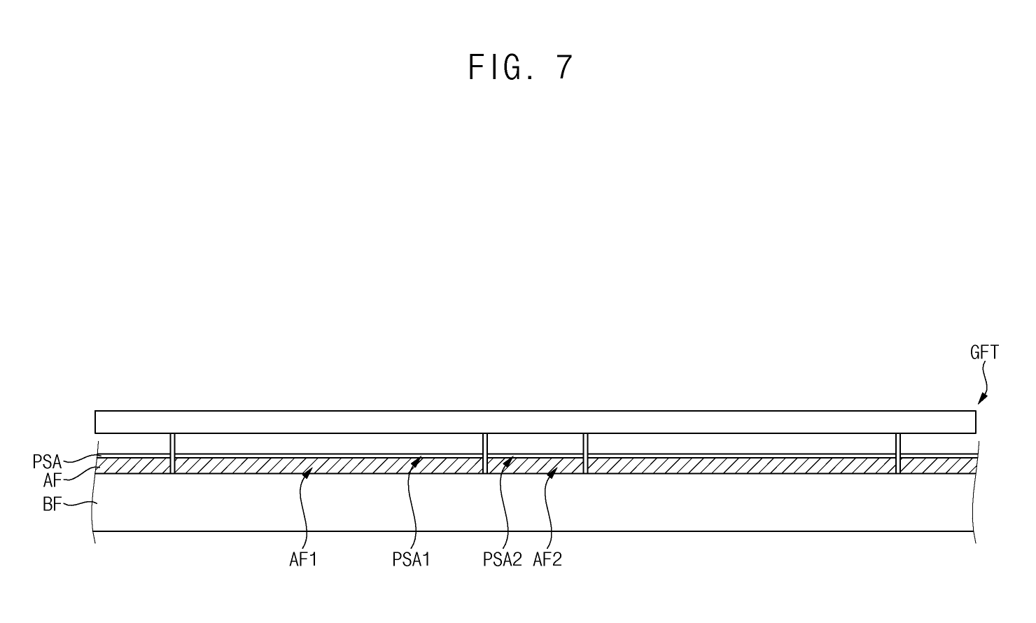

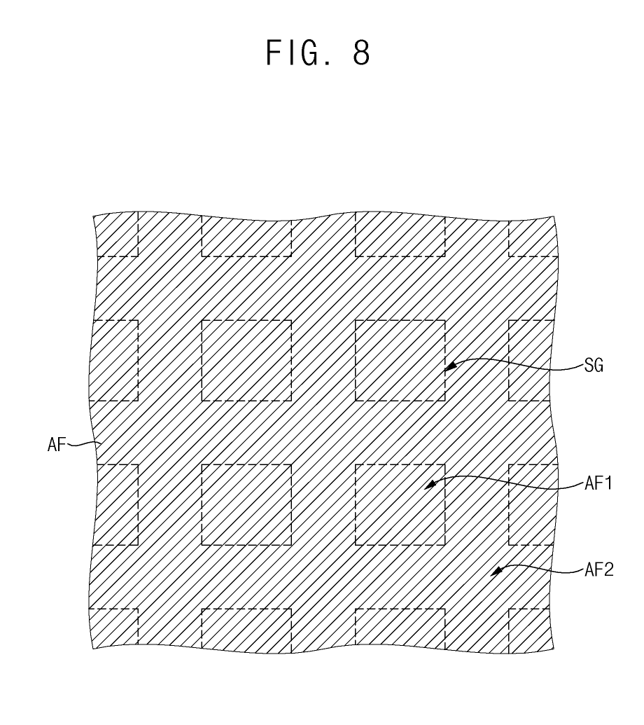

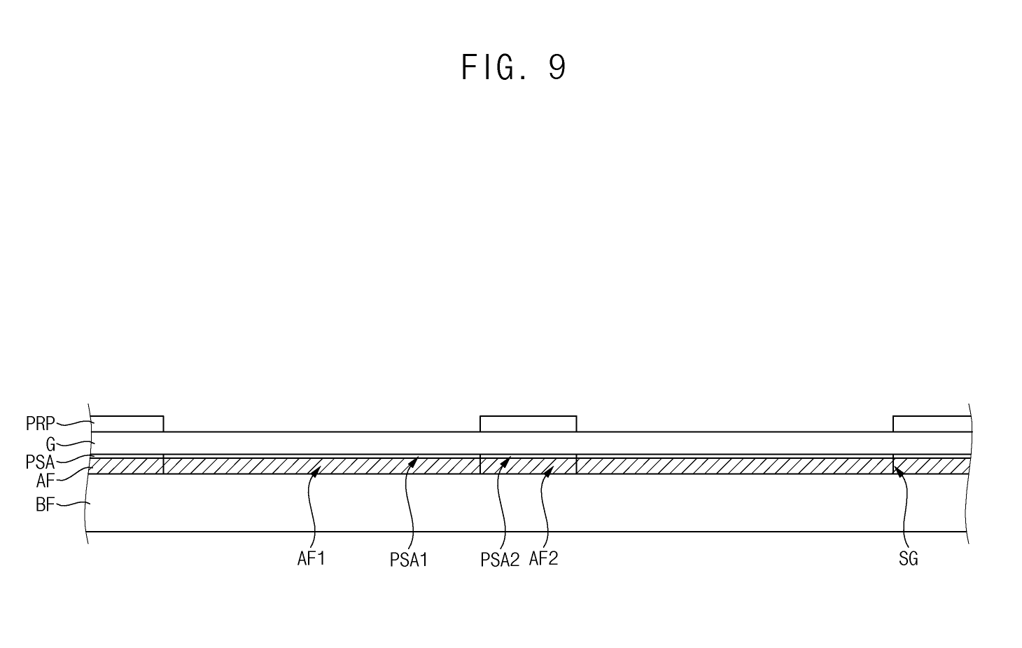

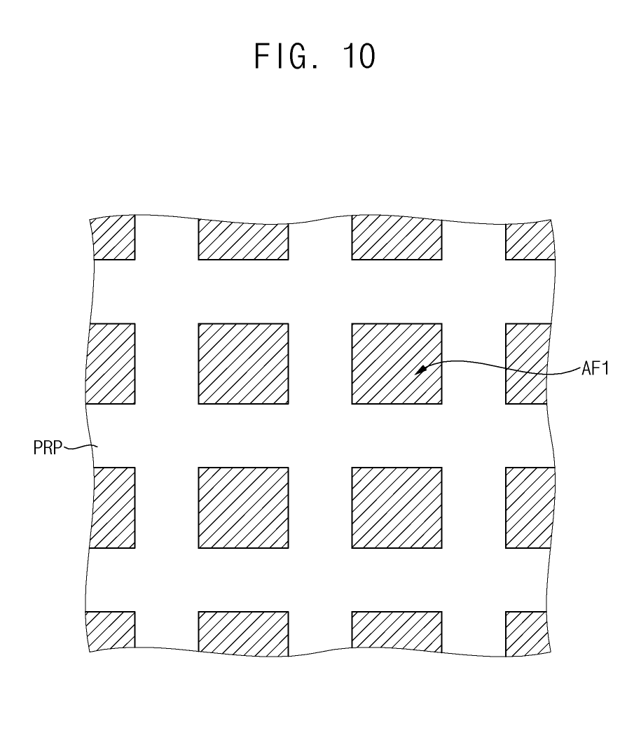

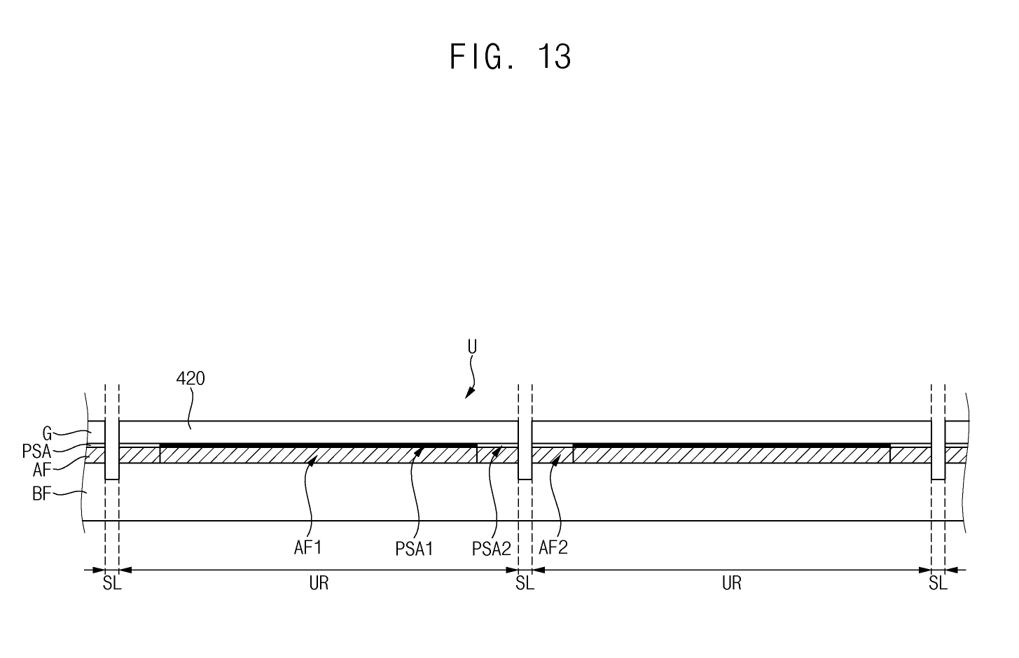

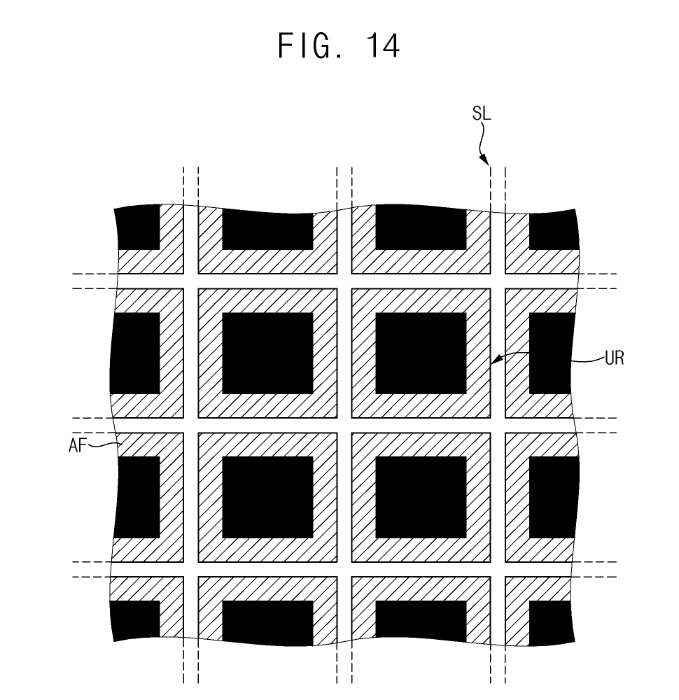

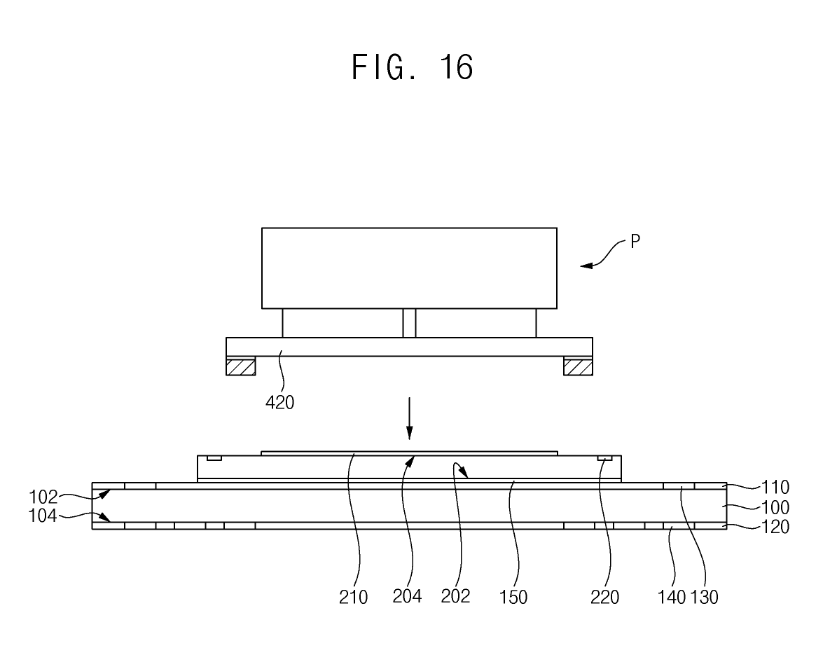

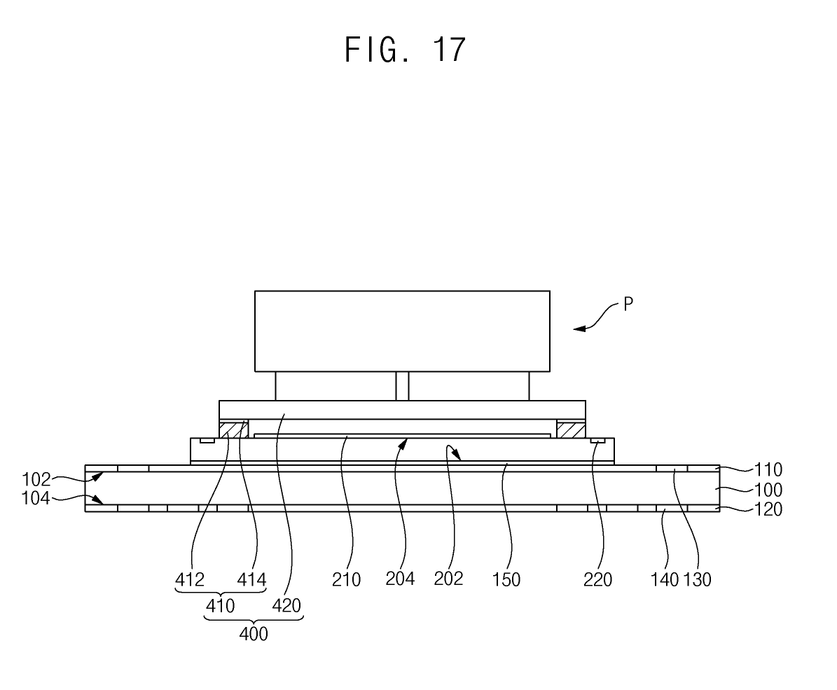

FIGS. 4 to 17 are view illustrating a method of manufacturing a semiconductor package in accordance with one or more example embodiments. FIGS. 4 to 8 and 10 to 16 are cross-sectional views illustrating a method of manufacturing a semiconductor package in accordance with one or more example embodiments. FIG. 7 is a plan view illustrating an adhesive film layer of FIG. 6. FIG. 10 is a plan view illustrating FIG. 9. FIG. 14 is a plan view illustrating a lens-covering portion of FIG. 13.

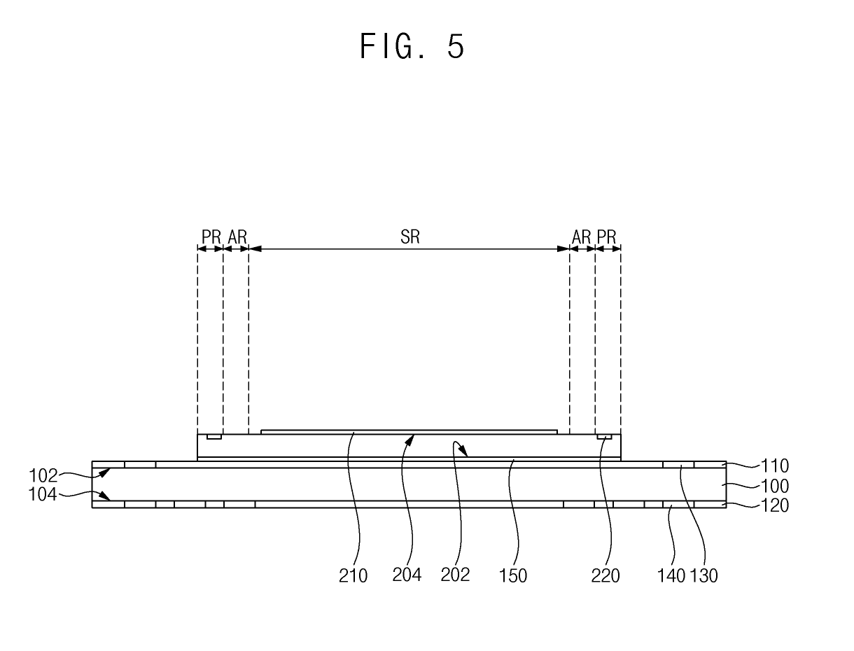

Referring to FIGS. 4 and 5, first, an image sensor chip 200 may be attached to a package substrate 100 using an adhesive layer 150.

In one or more example embodiments, the package substrate 100 may be a multi-layered circuit board as a package board comprising an upper surface 102 and a lower surface 104 opposite the upper surface 102. For example, the package substrate 100 may be a printed circuit board (PCB) including wirings respectively provided in a plurality of layers and vias for connecting the wirings.

The package substrate 100 may include an upper insulation layer 110 disposed on the upper surface 102 and a lower insulation layer 120 disposed on the lower surface 104. Additionally, the package substrate 100 may include upper substrate pads 130 and lower substrate pads 140.

As illustrated in FIG. 4, an adhesive layer 150 may be formed on the upper surface 102 of the package substrate 100. The adhesive layer 150 may include, for example, a liquid epoxy, an adhesive tape, or a conductive medium, but is not limited thereto.

As illustrated in FIG. 5, the image sensor chip 200 may be attached onto the adhesive layer 150.

In one or more example embodiments, the image sensor chip 200 may have a first surface 202 and a second surface 204 opposite the first surface 202. The image sensor chip 200 may have a sensing region SR, an adhesive region AR surrounding the sensing region SR, and a pad region PR surrounding the adhesive region AR on the second surface 204. The image sensor chip 200 may include a lens layer 210 further comprising a plurality of lenses 212 (see FIG. 3) in the sensing region SR on the second surface 204, and chip pads in the pad region PR. The image sensor chip 200 may be attached onto the adhesive layer 150 such that the first surface 202 faces the upper surface 102 of the package substrate 100.

The plurality of lenses 212 may include hemispherical microlenses arranged in an array form. The hemispherical microlenses may focus an incident light on the image sensor chip 200. The chip pads 220 may surround the plurality of lenses.

Referring to FIGS. 6 to 17, a lens-covering portion 400 may be formed, and the lens-covering portion 400 may be adhered to the image sensor chip 200 to cover the lens layer 210 on the image sensor chip 200.

As illustrated in FIGS. 6 to 8, an adhesive film layer AF and a photocurable adhesive layer PSA may be sequentially formed on a base film BF. For example, the base film BF may include a silicon substrate, but is not limited thereto. The adhesive film layer AF may be formed on the base film BF. The adhesive film layer AF may include an adhesive film material such as a die attach film (DAF). The adhesive film layer AF may be formed on the base film BF in a semi-cured state (B-Stage). Accordingly, the adhesive film layer AF may be adhered to the image sensor chip 200 in a cured state (C-Stage) as will be described later.

The photocurable adhesive layer PSA may be formed on the adhesive film layer AF. The photocurable adhesive layer PSA may include a pressure sensitive adhesive. When ultraviolet (UV) rays are irradiated to the photocurable adhesive layer PSA, the photocurable adhesive layer PSA may weaken or lose its adhesive strength.

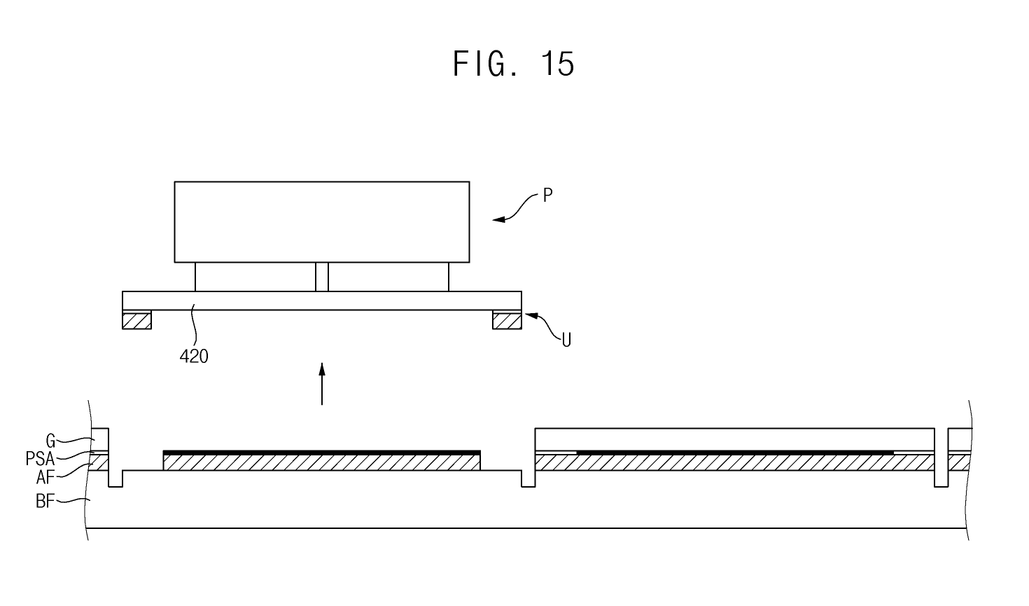

The adhesive film layer AF may have a first portion AF1 and a second portion AF2 divided by a separation groove SG. The separation groove SG may be formed by pressurizing a groove forming tool GFT such as a cutting frame onto the photocurable adhesive layer PSA and the adhesive film layer AF. The separation groove SG may have a shape in which quadrangular patterns are repeatedly arranged to be spaced apart from each other in the form of an array, but is not limited thereto and may comprise other shapes or combinations of shapes as well. Among the adhesive film layers AF, an area closed by the quadrangular patterns may correspond to the first portion AF1, and an area formed by a space between the quadrangular patterns may correspond to the second portion AF2. As will be described later, the separation groove SG may facilitate forming the adhesive film layer AF into one or more individual rectangular annular shapes when separating a lens cover unit U (see FIG. 15).

The photocurable adhesive layer PSA may have a first portion PSA1 and a second portion PSA2. The first portion PSA1 of the photocurable adhesive layer PSA may correspond to a portion overlapping the first portion AF1 of the adhesive film layer AF when viewed in a plan view. The second portion PSA2 of the photocurable adhesive layer PSA may correspond to a portion overlapping the second portion AF2 of the adhesive film layer AF when viewed in a plan view.

As illustrated in FIGS. 9 and 10, a glass layer G may be formed on the photocurable adhesive layer PSA, and a photoresist pattern PRP may be formed on the glass layer G. First, the glass layer G may be formed on the photocurable adhesive layer PSA. The glass layer G may be a transparent plate-shaped member and may be formed to be adhered on the photocurable adhesive layer PSA. The glass layer G may include a material such as a transparent glass or a transparent resin, but is not limited thereto.

Then, a photoresist layer may be formed on the glass layer G, and the photoresist layer may be patterned to form the photoresist pattern PRP. The photoresist pattern PRP may have a plurality of openings that are spaced apart from each other in the form of an array. Each of the plurality of openings may have a rectangular shape corresponding to the first portion AF1. The respective shapes of the plurality of openings may be formed to correspond to the shape of the separation groove SG. In this embodiment, a method of performing an exposure process using the photoresist pattern PRP as a mask has been described, but is not limited thereto, and one or more other patterning methods may also be used. For example, the exposure process may be performed using metal masks in which a plurality of openings are repeatedly arranged to be spaced apart from each other in the form of an array.

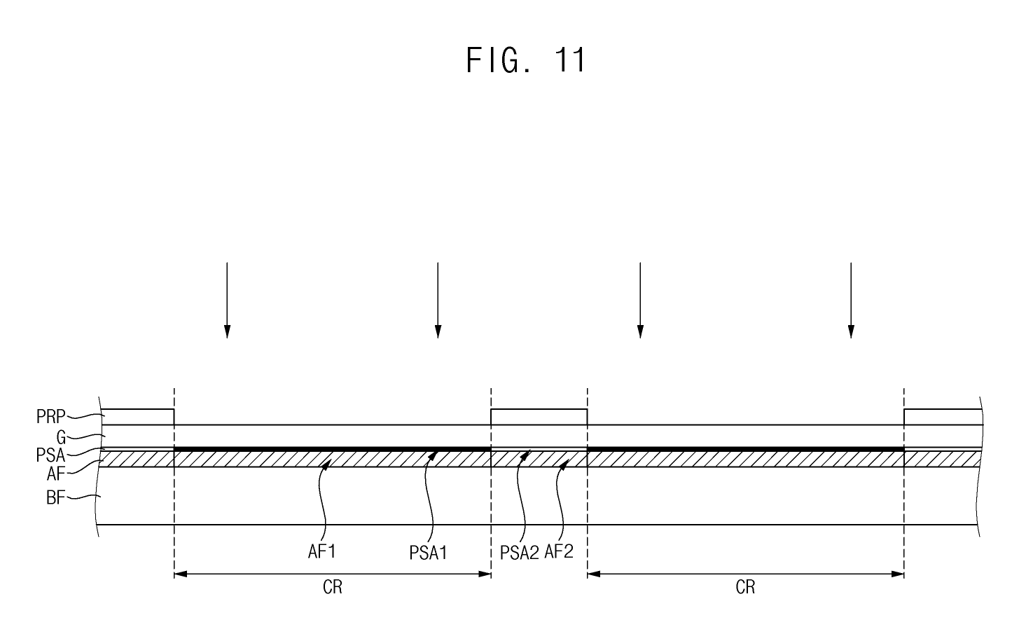

As illustrated in FIG. 11, an exposure process may be performed to cure a portion of the photocurable adhesive layer PSA exposed by the photoresist pattern PRP. The exposure process may be performed using, for example, UV light. When viewed in a plan view, because the glass layer G may comprise a transparent material such as transparent glass or transparent resin, the portion of the photocurable adhesive layer PSA exposed by the photoresist pattern PRP may be irradiated with the UV light. An exposure process may be performed on the photoresist pattern PRP so that the portion of the photocurable adhesive layer PSA exposed by the photoresist pattern PRP may be cured. As the portion of the photocurable adhesive layer PSA exposed by the photoresist pattern PRP is irradiated with the UV light, the photocurable adhesive layer PSA may weaken or lose its adhesive strength. For example, the first portion PSA1 of the photocurable adhesive layer PSA exposed by the opening may be cured. The portion of the photocurable adhesive layer PSA exposed by the opening of the photoresist pattern PRP may be a cover region CR. A portion of the photocurable adhesive layer PSA covered by the photoresist pattern PRP may not be cured in the exposure process. For example, the second portion PSA2 of the photocurable adhesive layer PSA may not be cured. The portion of the photocurable adhesive layer PSA covered by the photoresist pattern PRP may have a shape corresponding to the photoresist pattern PRP. Because the uncured photocurable adhesive layer PSA exists in a semi-cured state to maintain its adhesive strength, the uncured photocurable adhesive layer PSA may serve to adhere the glass layer G to the adhesive film layer AF.

Then, the photoresist pattern PRP may be removed. A region partitioned by a scribe lane SL may form a unit region U. The unit region UR may have a rectangular shape. The unit region U may correspond to a region for forming a lens cover unit U by performing a sawing process.

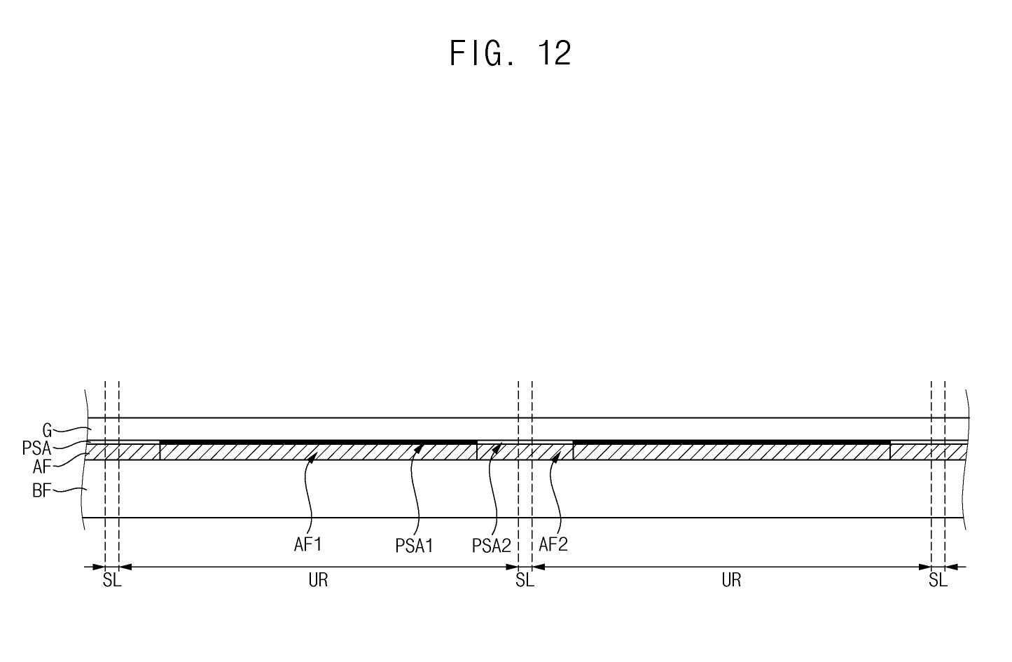

As illustrated in FIGS. 12 to 14, the lens cover unit U may be formed by performing a singulation or separation process (e.g., a sawing process) to form a plurality of individual lens cover portions.

In particular, the photoresist pattern PRP may be removed, and the sawing process may be performed on the glass layer G, the photocurable adhesive layer PSA, the adhesive film layer AF, and the base film BF to singularize (i.e., separate) the lens-covering portion 400. The sawing process may use a blade, a laser, or the like, but is not limited thereto. The adhesive film layer AF or the glass layer G may include an alignment mark for setting scribe lanes SL as a guide when the sawing process is performed. The scribe lanes SL may be set based on the alignment mark. The scribe lines SL may comprise one or more extension lines extending perpendicular to and intersecting each other to partition a cover region CR.

A sawing process may be performed to cut the glass layer G, the photocurable adhesive layer PSA, and the adhesive film layer AF on the scribe lane S. For example, the second portion AF2 of the adhesive film layer AF may be cut. Additionally, a portion of the base film BF may be cut along the scribe lanes SL. The glass layer G may be cut along a boundary of the unit region UR to form a glass 420. Accordingly, the lens cover unit U including the glass 420, the photocurable adhesive layer PSA and the adhesive film layer AF corresponding to the unit region UR may be formed. The scribe lanes SL may be spaced apart from the cover region CR, and the lens cover unit U may be formed such that the second portion PSA2 of the photocurable adhesive layer PSA has an annular shape in a plan view.

As illustrated in FIGS. 15 to 17, the lens cover unit U may be separated using a picker P and then may be adhered to the image sensor chip 200 to complete the lens-covering portion 400.

First, the lens cover unit U may be separated from the base film BF using the picker P. The picker P may be a device that provides vacuum pressure to a suction nozzle connected to a vacuum passage to suction and elevate the lens cover unit U through the vacuum pressure. An upper surface of the glass 420 may be adsorbed and then the lens cover unit U may be lifted using the picker P. The cover region CR of the photocurable adhesive layer PSA may be cured by the exposure process and accordingly lose its adhesive strength. For example, the first portion PSA1 of the photocurable adhesive layer PSA may be cured and accordingly lose its adhesive strength. In contrary, the portion covered by the photoresist pattern PRP may not be cured and thus may maintain its adhesive strength, so that the glass 420 and the adhesive film layer AF may be adhered.

When the glass 420 is separated by the picker P, the second portion AF2 of the adhesive film layer AF may be separated together by the adhesive strength provided by the photocurable adhesive layer PSA. Because the adhesive film layer AF may exist in the semi-cured state (B-Stage), the first portion AF1 may remain on the base film BF, and the second portion AF2 may be adhered to the photocurable adhesive layer PSA and separated from the base film BF. For example, the first portion AF1 of the adhesive film layer AF corresponding to the cover region CR of the photocurable adhesive layer PSA may remain on the base film BF, and the second portion PSA2 of the photocurable adhesive film layer PSA that is not cured may be adhered to the photocurable adhesive layer PSA.

Accordingly, the second portion AF2 of the adhesive film layer AF of the lens cover unit U may have a shape corresponding to the quadrangular annular shape of the photocurable adhesive layer PSA. Accordingly, the lens cover unit U may include the second portion AF2 of the adhesive film layer AF, the second portion PSA2 of the photocurable adhesive layer PSA corresponding thereto, and the glass 420 attached thereto. When viewed in a plan view, an outer surface of the second portion AF2 of the adhesive film layer AF, an outer surface of the second portion PSA2 of the photocurable adhesive layer PSA, and an outer surface of the glass 420 may be on a same plane.

When separating the lens cover unit U, because the outer surface of the adhesive film layer AF may be cut by the sawing process, the second portion AF2 of the adhesive film layer AF may be easily separated, but the portion of the adhesive film layer AF overlapping the cover region CR may maintain adhesive strength and thus may not be easily separated. In one or more example embodiments, after attaching the adhesive film layer AF on the base film BF, the separation groove SG may be formed in the adhesive film layer AF using a groove forming tool such as a cutting frame or a blade to have a shape substantially equal to the boundary of the cover region CR in advance so that the adhesive film layer AF may be easily separated in the rectangular annular shape.

Then, the lens cover unit U may be disposed on the image sensor chip 200. The lens cover unit U may be disposed such that the lens layer 210 of the image sensor chip 200 is accommodated in an internal space provided by the second portion AF2 of the adhesive film layer AF and the second portion PSA2 of the photocurable adhesive layer PSA extending in the annular shape. The lens cover unit U may be disposed such that the second portion AF2 of the adhesive film layer AF and the second portion PSA2 of the photocurable adhesive layer PSA are located inside a portion where the chip pads 220 are disposed to expose the chip pads 220 on the image sensor chip 200.

Then, the second portion AF2 of the adhesive film layer AF and the second portion PSA2 of the photocurable adhesive layer PSA may be cured using the picker P to complete the lens-covering portion 400. The picker P may provide an environment comprising a preset temperature and pressure at a portion of the second portion AF2 of the adhesive film layer AF and the second portion PSA2 of the photocurable adhesive layer PSA on the glass 420, so that the adhesive film layer AF and the photocurable adhesive layer PSA may be cured and adhered to the image sensor chip 200. That is, the picker P may be a vacuum collet that separates the lens cover unit U and applies pressure. For example, the adhesive film layer AF may be adhered to the image sensor chip 200 by applying an appropriate force at the glass transition temperature. The glass transition temperature may be within a range of about 120 °C to about 180°C. The second portion AF2 of the adhesive film layer AF may be cured to form a first adhesive film pattern 412. The second portion PSA2 of the photocurable adhesive layer PSA may be cured to form a second adhesive film pattern 414. Accordingly, the lens-covering portion 400 may include an adhesive film portion 410 attached to the second surface 204 of the image sensor chip 200 and the glass 420 supported on the adhesive film portion 410. The adhesive film portion 410 may include the first adhesive film pattern 412 attached to the second surface 204 of the image sensor chip 200 and the second adhesive film pattern 414 attached to the first adhesive film pattern 412.

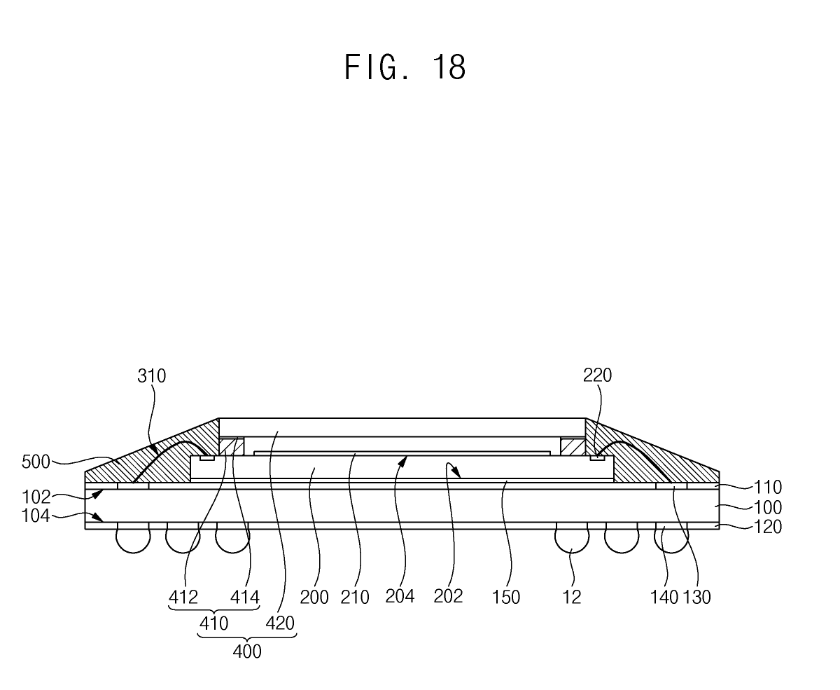

Referring to FIG. 18, bonding wires 310 may be formed to connect the package substrate 100 and the image sensor chip 200, and a molding member 500 may be formed on the package substrate 100.

In one or more example embodiments, the bonding wire 310 may electrically connect upper substrate pads 130 on the upper surface 102 of the package substrate 100 to the chip pads 220 on the image sensor chip 200. For example, a first end of one or more of the bonding wires 310 may be bonded on the upper substrate pad 130, and a second end of the one or more bonding wires 310 opposite the first end may be formed to be bonded to the chip pad 220. The bonding wire 310 may include a metal such as gold (Au), but is not limited thereto.

In one or more example embodiments, the molding member 500 may be formed on the package substrate 100 to cover the image sensor chip 200 and the bonding wires 310. The molding member 500 may be formed to cover a side surface of the glass 420 and a side surface of the adhesive film portion 410. The molding member 500 may be formed to cover the bonding wire 310. The molding member 500 may prevent the lens layer 210 of the image sensor chip 200 from being contaminated by external foreign substances together with the lens-covering portion 400. Additionally, the molding member 500 may protect the semiconductor package 10 including the image sensor chip 200 from external impact.

Then, an external connection member 12 may be formed on the lower surface 104 of the package substrate 100 to complete the semiconductor package of FIG. 1.

As described above, in the method of manufacturing the semiconductor package 10, the adhesive layer 150 may be formed on the package substrate 100. The image sensor chip 200 may be attached onto the adhesive layer 150. The lens-covering portion 400 for covering the plurality of lenses 212 on the image sensor chip 200 may be formed. The formation of the lens-covering portion 400 may include forming the adhesive film layer AF, the photocurable adhesive layer PSA, and the glass layer G on the base film BF. The photoresist pattern PRP may be formed on the glass layer G. The exposure process may be performed to cure a portion of the photocurable adhesive layer PSA. The lens cover unit U may be formed by removing the photoresist pattern PRP and performing a sawing process. The lens cover unit U may be separated using the picker P and adhered to the image sensor chip 200 to form the lens-covering portion 400.

Hereinafter, a semiconductor package in accordance with another example embodiment will be described.

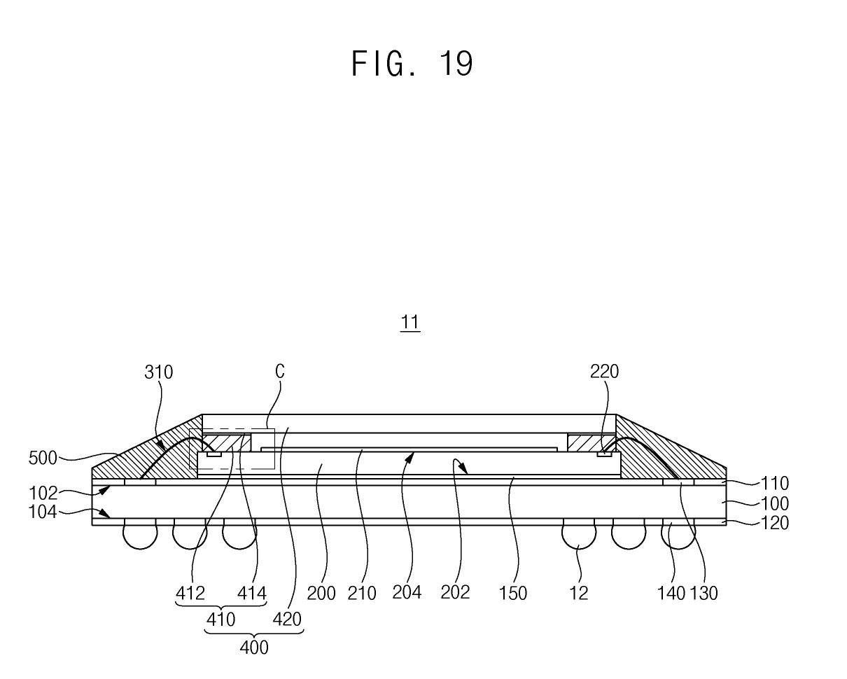

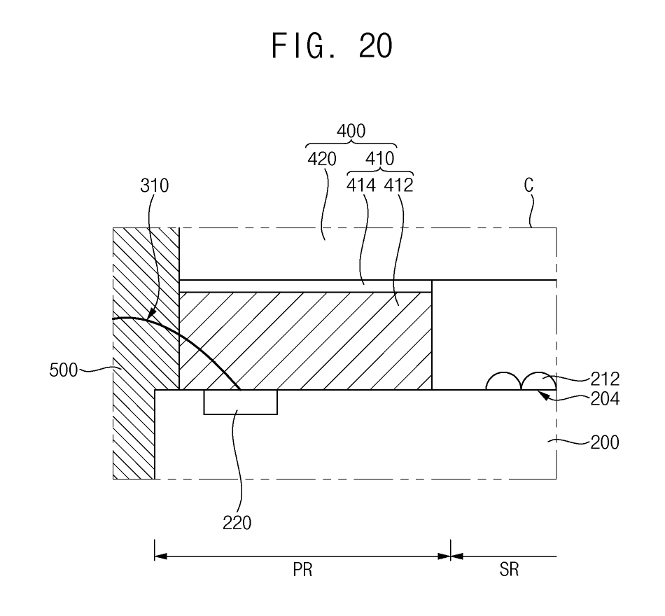

FIG. 19 is a cross-sectional view illustrating a semiconductor package in accordance with one or more example embodiments. FIG. 20 is an enlarged cross-sectional view illustrating portion ‘C’ in FIG. 19.

The semiconductor package 11 according to one or more example embodiments may include substantially the same elements as the semiconductor package described with reference to FIG. 1, except that an adhesive film portion 410 may cover chip pads 220. Accordingly, same reference numerals may be used to refer to the same or like elements and any further repetitive explanation concerning the above elements may be omitted.

Referring to FIGS. 19 and 20, a lens-covering portion 400 may be disposed on an image sensor chip 200. The image sensor chip 200 may have a sensing region SR and a pad region PR surrounding the sensing region SR on a second surface 204 thereof. The image sensor chip 200 may include a lens layer 210 in the sensing region SR. The image sensor chip 200 may include chip pads 220 in the pad region PR.

The lens-covering portion 400 may be disposed on the second surface 204 of the image sensor chip 200. The lens-covering portion 400 may include an adhesive film portion 410 and a glass 420 disposed to be supported on the adhesive film portion 410.

In one or more example embodiments, the adhesive film portion 410 may be disposed on the pad region PR of the image sensor chip 200. For example, the adhesive film portion 410 may be disposed to cover the chip pads 220 and a portion of a bonding wire 310 connected to the chip pad 220. The adhesive film portion 410 may be disposed to surround the sensing region SR on the second surface 204 of the image sensor chip 200. For example, the adhesive film portion 410 may have a rectangular ring shape, an annular shape, or any other polygonal ring shape along a peripheral region of the image sensor chip 200, but is not limited thereto.

Hereinafter, a method of manufacturing the semiconductor package of FIG. 19 will be described.

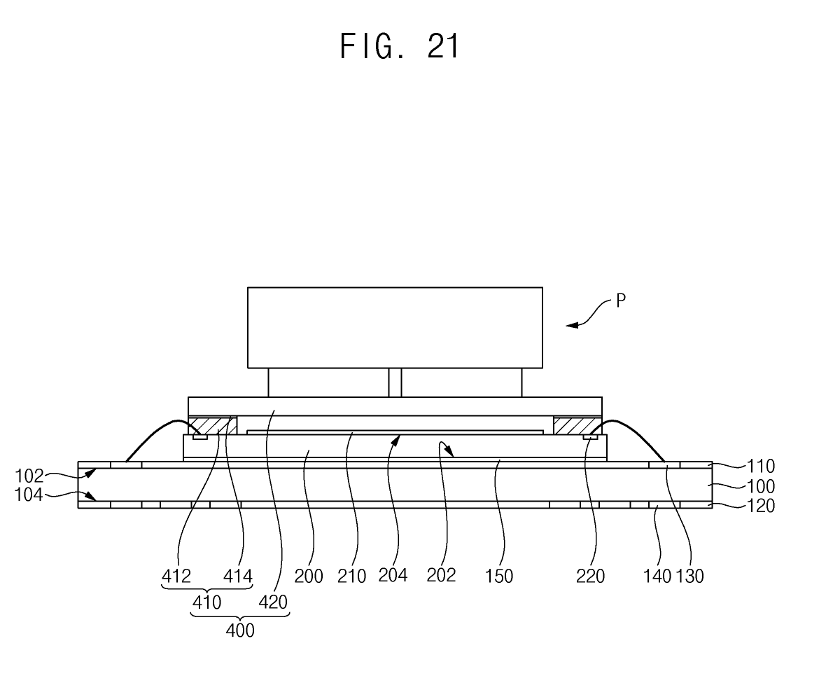

FIG. 21 is a cross-sectional view illustrating a method of manufacturing a semiconductor package in accordance with one or more example embodiments.

The method of manufacturing the semiconductor package 11 according to one or more example embodiments may include substantially the same components as the method of manufacturing the semiconductor package described with reference to FIGS. 4 to 15, except that an adhesive film portion 410 may be disposed to cover chip pads 220. Accordingly, same reference numerals may be used to refer to the same or like elements and any further repetitive explanation concerning the above elements may be omitted.

Referring to FIG. 21, a lens-covering portion 400 may be formed on an image sensor chip 200.

First, an adhesive layer 150 may be formed on a package substrate 100. An image sensor chip 200 may be attached onto the adhesive layer 150. Then, one or more bonding wires 310 may be formed to respectively connect one or more chip pads 220 to a upper substrate pad 130.

A lens cover unit U may be disposed such that an adhesive film layer AF covers the one or more chip pads 220 and a portion of the one or more bonding wires 310 connected to the chip pad 220. Because the adhesive film layer AF exists in a semi-cured state (B-stage), the one or more bonding wires 310 may not be damaged in the process of disposing the adhesive film layer AF to cover the portion of the one or more bonding wires 310.

Then, the adhesive film layer AF and the photocurable adhesive layer PSA may be cured using the picker P to complete the lens-covering portion 400.

According to an aspect of the disclosure, a method of manufacturing a semiconductor package, includes: preparing a package substrate including upper substrate pads; disposing an image sensor chip on the package substrate, the image sensor chip including a lens layer in a sensing region and chip pads in a pad region surrounding the sensing region; connecting the chip pads of the image sensor chip and the upper substrate pads via bonding wires; forming, on the image sensor chip, a lens-covering portion including a glass and an adhesive film portion having an annular shape or a rectangular ring shape on a lower surface of the glass; attaching the adhesive film portion of the lens-covering portion on the image sensor chip; and forming a molding member on the image sensor chip and the bonding wires.

The forming the lens-covering portion may include: forming an adhesive film layer, a photocurable film layer, and a glass layer including a transparent material on a base film; forming a photoresist pattern on the glass layer; performing an exposure process to cure a portion of the photocurable film layer exposed through the photoresist pattern; removing the photoresist pattern; and performing a singulation process to form a plurality of individual lens cover portions.

The photocurable film layer may include a plurality of unit regions partitioned by a plurality of scribe lanes extending perpendicularly to each other when viewed in a plan view, and the photoresist pattern may have an annular shape or a rectangular ring shape around a cover region in each of the plurality of unit regions.

The performing the exposure process to cure the portion of the photocurable film layer may include curing a portion of the photocurable film layer that overlaps the cover region exposed by the photoresist pattern when viewed in a plan view.

The performing the singulation process may include cutting the adhesive film layer, the photocurable film layer, and the glass layer along the plurality of scribe lanes.

The adhesive film layer may include a die attach film (DAF) material.

The photocurable film layer may include an ultraviolet (UV) curable material.

The forming the lens-covering portion may include: forming an adhesive film layer, a photocurable film layer, and a glass layer including a transparent material on a silicon substrate; disposing a metal mask on the glass layer; curing a portion of the photocurable film layer exposed through the metal mask; and performing a singulation process to form a plurality of individual lens-covering portions, and the metal mask may include a plurality of openings.

The attaching the adhesive film portion of the lens-covering portion on the image sensor chip may include: disposing the lens-covering portion on the image sensor chip such that the adhesive film portion faces the image sensor chip; and performing a thermocompression bonding process to solidify the adhesive film portion.

The disposing the lens-covering portion on the image sensor chip may include: disposing the adhesive film portion on the pad region so that the chip pads are exposed on the image sensor chip.

The disposing the lens-covering portion on the image sensor chip may include disposing the adhesive film portion on the pad region to cover the chip pads and a portion of the bonding wires connected to the chip pads.

According to an aspect of the disclosure, in a method of manufacturing a semiconductor package, a package substrate comprising upper substrate pads may be prepared. An image sensor chip may be disposed on the package substrate. The image sensor chip may include a lens layer in a sensing region and chip pads in a pad region surrounding the sensing region. The chip pads of the image sensor chip and the upper substrate pads may be connected via bonding wires. A lens-covering portion comprising a glass and an adhesive film portion having an annular shape or a rectangular ring shape may be formed on a lower surface of the glass. The adhesive film portion of the lens-covering portion may be attached on the image sensor chip. A molding member may be formed on the image sensor chip and the bonding wires.

In one or more example embodiments, the forming the lens-covering portion may include forming an adhesive film layer, a photocurable film layer, and a glass layer comprising a transparent material on a base film, forming a photoresist pattern on the glass layer, performing an exposure process to cure a portion of the photocurable film layer exposed through the photoresist pattern, removing the photoresist pattern and performing a singulation process to form a plurality of individual lens cover portions.

In one or more example embodiments, the photocurable film layer may include a plurality of unit regions partitioned by a plurality of scribe lanes extending perpendicularly to each other when viewed in a plan view and the photoresist pattern may have an annular shape or a rectangular ring shape around a cover region in each of the plurality of unit regions.

In one or more example embodiments, the performing the exposure process to cure the portion of the photocurable film layer may include curing a portion of the photocurable film layer that overlaps the cover region exposed by the photoresist pattern when viewed in a plan view.

In one or more example embodiments, the performing the singulation process may include cutting the adhesive film layer, the photocurable film layer, and the glass layer along the plurality of scribe lanes.

In one or more example embodiments, the adhesive film layer may include a die attach film (DAF) material.

In one or more example embodiments, the photocurable film layer may include an ultraviolet (UV) curable material.

In one or more example embodiments, the forming the lens-covering portion may include forming an adhesive film layer, a photocurable film layer, and a glass layer comprising a transparent material on a silicon substrate, disposing a metal mask on the glass layer, curing a portion of the photocurable film layer exposed through the metal mask and performing a singulation process to form a plurality of individual lens-covering portions, and wherein the metal mask comprises a plurality of openings.

In one or more example embodiments, the attaching the adhesive film portion of the lens-covering portion on the image sensor chip may include disposing the lens-covering portion on the image sensor chip such that the adhesive film portion faces the image sensor chip and performing a thermocompression bonding process to solidify the adhesive film portion.

In one or more example embodiments, the disposing the lens-covering portion on the image sensor chip may include disposing the adhesive film portion on the pad region so that the chip pads are exposed on the image sensor chip.

In one or more example embodiments, the disposing the lens-covering portion on the image sensor chip may include disposing the adhesive film portion on the pad region to cover the chip pads and a portion of the bonding wires connected to the chip pads.

The foregoing is illustrative of one or more example embodiments and is not to be construed as limiting thereof. Although one or more example embodiments have been described, those skilled in the art will readily appreciate that many modifications are possible in the one or more example embodiments without materially departing from the novel teachings and advantages of the disclosure. Accordingly, all such modifications are intended to be included within the scope of the one or more example embodiments as defined in the claims.

What is claimed is:

1. A semiconductor package, comprising:
a package substrate comprising upper substrate pads on an upper surface of the package substrate;
an image sensor chip on the upper surface of the package substrate, the image sensor chip comprising chip pads on an upper surface of the image sensor chip;
bonding wires connecting the upper substrate pads of the package substrate and the chip pads;
a lens-covering portion comprising a glass and an adhesive film portion having an annular shape or a rectangular ring shape on a lower surface of the glass, the lens-covering portion being adhered on the image sensor chip by the adhesive film portion between the image sensor chip and the glass; and
a molding member on the image sensor chip and the bonding wires.

2. The semiconductor package of claim 1, wherein the adhesive film portion comprises:
a first adhesive film pattern comprising a die attach film (DAF) material; and
a second adhesive film pattern between the glass and the first adhesive film pattern, the second adhesive film pattern comprising a photocurable material.

3. The semiconductor package of claim 2, wherein the photocurable material comprises an ultraviolet (UV) curable material.

4. The semiconductor package of claim 2, wherein the photocurable material comprises a pressure sensitive adhesive (PSA).

5. The semiconductor package of claim 2, wherein the first adhesive film pattern has a first thickness, and the second adhesive film pattern has a second thickness less than the first thickness.

6. The semiconductor package of claim 1, wherein an outer surface of the adhesive film portion is coplanar with an outer surface of the glass, when viewed in a plan view.

7. The semiconductor package of claim 1, wherein the upper surface of the image sensor chip further comprises a sensing region and a pad region surrounding the sensing region, and
wherein the chip pads and the adhesive film portion are on the pad region and around the sensing region.

8. The semiconductor package of claim 7, wherein the chip pads are outside an outer surface of the adhesive film portion on the pad region in plan view.

9. The semiconductor package of claim 7, wherein the adhesive film portion is on the chip pads and portions of the bonding wires connected to the chip pads.

10. The semiconductor package of claim 1, wherein the molding member is on an outer surface of the glass and an outer surface of the adhesive film portion.

11. A semiconductor package comprising:
a package substrate;
an image sensor chip on an upper surface of the package substrate, the image sensor chip comprising a sensing region, an adhesive region surrounding the sensing region, a pad region surrounding the adhesive region, and chip pads on the pad region;
bonding wires connecting upper substrate pads of the package substrate and the chip pads;
a lens-covering portion comprising an adhesive film portion on the adhesive region of the image sensor chip and a glass on the adhesive film portion, the glass on the sensing region; and
a molding member on the image sensor chip and the bonding wires,
wherein the adhesive film portion comprises:
a first adhesive film pattern on the adhesive region of the image sensor chip; and
a second adhesive film pattern on the first adhesive film pattern, the second adhesive film pattern comprising a photocurable material.

12. The semiconductor package of claim 11, wherein the first adhesive film pattern comprises a die attach film (DAF) material, and
wherein the second adhesive film pattern comprises an ultraviolet(UV) curable material.

13. The semiconductor package of claim 11, wherein the second adhesive film pattern comprises a pressure sensitive adhesive (PSA).

14. The semiconductor package of claim 11, wherein the first adhesive film pattern has a first thickness, and the second adhesive film pattern has a second thickness less than the first thickness.

15. The semiconductor package of claim 11, wherein the first adhesive film pattern has a first width, and the second adhesive film pattern has a second width less than the first width.

16. The semiconductor package of claim 11, wherein an outer surface of the adhesive film portion is coplanar with an outer surface of the glass, when viewed in a plan view.

17. The semiconductor package of claim 11, wherein the chip pads are outside an outer surface of the adhesive film portion on the pad region when viewed in a plan view.

18. The semiconductor package of claim 11, wherein the adhesive film portion is on the chip pads and portions of the bonding wires connected to the chip pads.

19. The semiconductor package of claim 11, wherein the molding member is on an outer surface of the glass and an outer surface of the adhesive film portion.

20. A semiconductor package comprising:
a package substrate;
an image sensor chip on an upper surface of the package substrate, the image sensor chip being electrically connected to the package substrate and comprising a sensing region and an adhesive region around the sensing region;
a first adhesive film pattern on the adhesive region of the image sensor chip and having a first width;
a second adhesive film pattern on the first adhesive film pattern, the second adhesive film pattern having a second width substantially equal to the first width, the second adhesive film pattern comprising a photocurable material;
a lens-covering portion comprising a glass on the second adhesive film pattern and the sensing region; and
a molding member on the image sensor chip,
wherein the molding member is on an outer surface of the first adhesive film pattern, an outer surface of the second adhesive film pattern, and an outer surface of the glass.
